(19) United States
(12) Patent Application Publication
(10) Pub. No.: US 2024/0194386 A1
(43) Pub. Date: Jun. 13, 2024

(54) INDUCTOR STRUCTURE, MAGNETICALLY PERMEABLE BODY AND MANUFACTURING METHOD THEREOF

(71) Applicant: PHOENIX PIONEER TECHNOLOGY CO., LTD., Hsinchu County (TW)

(72) Inventors: Shih-Ping HSU, Hsinchu County (TW); Pao-Hung CHOU, Hsinchu County (TW)

(73) Assignee: PHOENIX PIONEER TECHNOLOGY CO., LTD., Hsinchu County (TW)

(21) Appl. No.: 18/534,196

(22) Filed: Dec. 8, 2023

(30) Foreign Application Priority Data
Dec. 9, 2022 (TW) 111147473

(51) Int. Cl. H01F 27/24; H01F 27/28; H01F 41/02; H01F 41/04

(52) U.S. Cl. CPC H01F 27/24; H01F 27/2804; H01F 41/0206; H01F 41/041; H01F 2027/2809

(57) ABSTRACT

An inductor structure is provided, in which an inductance coil in the shape of a toroidal coil or a helical coil is arranged in an insulator, and a magnetically permeable body made of a magnetically permeable material is a multi-layer stacked structure and arranged in the inductance coil, where the magnetically permeable body is free from being electrically connected to the inductance coil. Therefore, the magnetically permeable body made of a magnetically permeable material in the form of a multi-layer stacked structure may effectively improve the electrical characteristics of the inductor structure.

### BACKGROUND

### 1. Technical Field

The present disclosure relates to an inductance element used in a semiconductor packaging process, and more particularly, to an inductor structure and a magnetically permeable body and a manufacturing method thereof.

### 2. Description of Related Art

General semiconductor application devices, such as communication or high-frequency semiconductor devices, often need to electrically connect most of the radio-frequency passive elements such as resistors, inductors, capacitors and oscillators to the packaged semiconductor chip, so that the semiconductor chip has a specific current characteristic or emits a signal. For example, there are many types of conventional inductors, which are mostly used to suppress power supply noise.

At present, the semiconductor industry is aiming at light, thin and small electronic equipment, and it is mainly to develop a single element towards miniaturization or thinning. In a semiconductor package 1 shown in FIG. 1A and FIG. 1B, a coil-type inductor 12 is integrated on a package substrate 10 having a circuit layer 11, a semiconductor chip 13 is arranged on the package substrate 10, and the semiconductor chip 13 is electrically connected to electrode pads 110 of the circuit layer 11 via a plurality of bonding wires 130, wherein sputtering and vapor deposition techniques can be used to produce a thinner metal film to form the coil-type inductor 12, that is, a thin film inductor.

However, the coil-type inductor 12 is disposed on the package substrate 10, so that the inductance value generated by the coil-type inductor 12 is too small to meet the requirement. To increase the inductance value, it is necessary to increase the area or volume of the coil-type inductor 12, such that the semiconductor package 1 cannot meet the needs of products such as miniaturization, thinness, lightness and shortness.

Therefore, a configuration of increasing the magnetically permeable material has been developed in the industry to increase the inductance value. A conventional package substrate (not shown) is equipped with a magnetic core, such as ferrite or iron oxide, in its coil to achieve the above purpose.

However, the volume of the conventional bulk magnetic core is too large, causing a large eddy current effect, resulting in loss and limiting the electrical characteristics of the inductance element.

Therefore, how to overcome various problems of the above-mentioned prior art has become a difficult problem urgently to be overcome in the industry.

### SUMMARY

In view of the various deficiencies of the prior art, the present disclosure provides a magnetically permeable body, which comprises: an insulating carrier layer; and a first magnetically permeable group and a second magnetically permeable group stacked in layers on the insulating carrier layer, wherein the first magnetically permeable group includes a first seed layer and a first magnetically permeable alloy layer bonded to the first seed layer, the second magnetically permeable group includes a second seed layer and a second magnetically permeable alloy layer bonded to the second seed layer, and wherein the first seed layer, the first magnetically permeable alloy layer, the second seed layer and the second magnetically permeable alloy layer are sequentially stacked above the insulating carrier layer, and the first magnetically permeable alloy layer and the second seed layer are between the first seed layer and the second magnetically permeable alloy layer.

The present disclosure further provides a method of manufacturing a magnetically permeable body, the method comprises: providing an insulating carrier layer; forming a first seed layer of a first magnetically permeable group on the insulating carrier layer, electroplating a first magnetically permeable alloy layer of the first magnetically permeable group on the first seed layer via a patterning process, and removing the first seed layer outside a layout range of the first magnetically permeable alloy layer via an etching process; and forming a second seed layer of a second magnetically permeable group on the first magnetically permeable alloy layer, electroplating a second magnetically permeable alloy layer of the second magnetically permeable group on the second seed layer via a patterning process, and removing the second seed layer outside a layout range of the second magnetically permeable alloy layer via an etching process; wherein the first magnetically permeable group and the second magnetically permeable group are stacked in layers on the insulating carrier layer, the first magnetically permeable group includes the first seed layer and the first magnetically permeable alloy layer bonded to the first seed layer, the second magnetically permeable group includes the second seed layer and the second magnetically permeable alloy layer bonded to the second seed layer, and wherein the first seed layer, the first magnetically permeable alloy layer, the second seed layer and the second magnetically permeable alloy layer are sequentially stacked above the insulating carrier layer, and the first magnetically permeable alloy layer and the second seed layer are between the first seed layer and the second magnetically permeable alloy layer.

In the aforementioned magnetically permeable body and method, the first magnetically permeable alloy layer and/or the second magnetically permeable alloy layer contains a binary or ternary alloy consisting of iron, nickel, cobalt, manganese and zinc.

In the aforementioned magnetically permeable body and method, the first seed layer and/or the second seed layer is a non-pure copper seed layer, and the seed layer includes nickel or an alloy thereof, a conductive polymer material, a semiconductive metal oxide (such as nickel oxide), a semiconductive inorganic oxide (such as silicon oxide) and the like, wherein the thickness of the seed layer is in micrometer or nanometer, so that the seed layer can conduct electricity but have a higher resistance value. For example, the conductive polymer material includes one of polyaniline, polypyrrole, polythiophene, p-phenylene vinylene, or derivative thereof.

In the aforementioned magnetically permeable body and method, the first magnetically permeable group and the second magnetically permeable group have an insulating isolation layer formed therebetween.

In the aforementioned magnetically permeable body and method, the first magnetically permeable group, the second magnetically permeable group, a third magnetically permeable group and a fourth magnetically permeable group are sequentially stacked above the insulating carrier layer, and the second magnetically permeable group and the third magnetically permeable group have an insulating isolation layer formed therebetween, wherein the third magnetically permeable group includes a third seed layer and a third magnetically permeable alloy layer bonded to the third seed layer, and the fourth magnetically permeable group includes a fourth seed layer and a fourth magnetically permeable alloy layer bonded to the fourth seed layer.

The present disclosure further provides an inductor structure, which comprises: an insulator having a first side and a second side opposing the first side; at least one inductance coil embedded in the insulator; a conductive circuit embedded in the insulator and electrically connected to the inductance coil, wherein the conductive circuit includes a plurality of electrode pads disposed on the first side and partially exposed from the first side, and a plurality of welding pads disposed on the second side and partially exposed from the second side; and the aforementioned magnetically permeable body embedded in the inductance coil in the insulator, wherein the magnetically permeable body is free from being electrically connected to the inductance coil.

The present disclosure further provides a method of manufacturing an inductor structure, the method comprises: providing a carrier board having a metal surface; forming a first circuit structure and a first inductance circuit portion on the carrier board, wherein the first circuit structure has at least one first dielectric layer and a plurality of electrode pads; forming the aforementioned magnetically permeable body on the first dielectric layer, wherein the first dielectric layer is used as the insulating carrier layer; forming a second inductance circuit portion on the first inductance circuit portion and the first dielectric layer; forming a second dielectric layer to cover the second inductance circuit portion and the magnetically permeable body, wherein part of a surface of the second inductance circuit portion is exposed from the second dielectric layer; forming a third inductance circuit portion on the second dielectric layer, wherein the first inductance circuit portion, the second inductance circuit portion and the third inductance circuit portion are combined into an inductance coil; forming a second circuit structure on the third inductance circuit portion and the second dielectric layer, wherein the second circuit structure has at least one third dielectric layer and a plurality of welding pads, and the plurality of welding pads are exposed from the third dielectric layer, wherein the first dielectric layer, the second dielectric layer and the third dielectric layer are served as an insulator, and the first circuit structure and the second circuit structure form a conductive circuit that is electrically connected to the inductance coil; and removing the carrier board to expose the plurality of electrode pads, wherein the insulator has a first side and a second side opposing the first side, wherein the plurality of electrode pads are disposed on the first side and are partially exposed from the first side, and the plurality of welding pads are disposed on the second side and are partially exposed from the second side.

In the aforementioned inductor structure and method, the present disclosure further comprises electrically bonding to package a capacitive element and/or an active chip on the plurality of electrode pads.

In the aforementioned inductor structure and method, a material for forming the insulator is a photosensitive or non-photosensitive insulating material and includes Ajinomoto build-up film, photosensitive resin, polyimide, bismaleimide triazine, flame resistant 5 (FR5) prepreg, molding compound, or epoxy molding compound.

In the aforementioned inductor structure and method, the magnetically permeable body is vertically divided, horizontally divided, or grid-like divided.

As can be seen from the above, in the inductor structure of the present disclosure and the magnetically permeable body and the manufacturing method thereof, the magnetically permeable body is made of a magnetically permeable material to increase the magnetic permeability. Therefore, via the design of the magnetically permeable body, the inductor structure can improve its ability to resist electromagnetic interference, and can reduce the influence of eddy current and magnetic loss on the Q value.

Moreover, the copper-free magnetically permeable material is electroplated or deposited in the insulator to form a magnetically permeable body by using a patterned build-up circuit manufacturing method of a printed circuit board (PCB) or an IC carrier board, so that the precision control of the magnetically permeable body is excellent. Therefore, compared with the prior art, the precision control of the inductance value of the inductor structure of the present disclosure is excellent. Moreover, because the inductor structure of the present disclosure can be embedded in the package substrate, the production process can be reduced to reduce costs, and because tiny inductance elements can be produced, the purpose of miniaturization or thinning of products can be achieved.

Furthermore, the inductance circuit is designed to be located in the insulator by using the IC carrier board manufacturing process, so compared with the prior art, the inductor structure of the present disclosure can reduce the manufacturing cost.

Also, compared to the configuration of the iron core blocks of the prior art, the thickness of the inductor structure of the present disclosure can be adjusted according to requirements without the need to configure iron core blocks. Therefore, the present disclosure is easier to miniaturize, so that the application products such as package substrates can meet the miniaturization requirements.

### BRIEF DESCRIPTION OF THE DRAWINGS

FIG. 1A is a schematic cross-sectional view of a conventional semiconductor package.

FIG. 1B is a schematic partial perspective view of FIG. 1A.

FIG. 2A is a schematic cross-sectional view of a magnetically permeable body according to a first embodiment of the present disclosure.

FIG. 2B is a schematic cross-sectional view of the magnetically permeable body according to a second embodiment of the present disclosure.

FIG. 2C is a schematic cross-sectional view of the magnetically permeable body according to a third embodiment of the present disclosure.

FIG. 3A is a schematic cross-sectional view of an inductor structure according to the present disclosure.

FIG. 3B to FIG. 3G are schematic cross-sectional views illustrating a manufacturing method of the inductor structure according to the present disclosure.

FIG. 4A-1 is a schematic cross-sectional view according to another embodiment of FIG. 3G.

FIG. 4A-2 is a schematic partial top plan view of FIG. 4A-1.

FIG. 4B-1 is a schematic cross-sectional view of another aspect of FIG. 4A-1.

FIG. 4B-2 and FIG. 4C are schematic top plan views of other aspects of FIG. 4A-2.

FIG. 5 is a schematic cross-sectional view of an application of the inductor structure according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

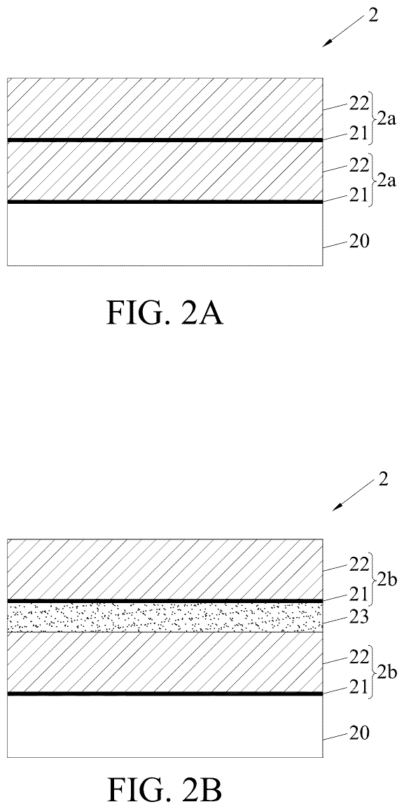

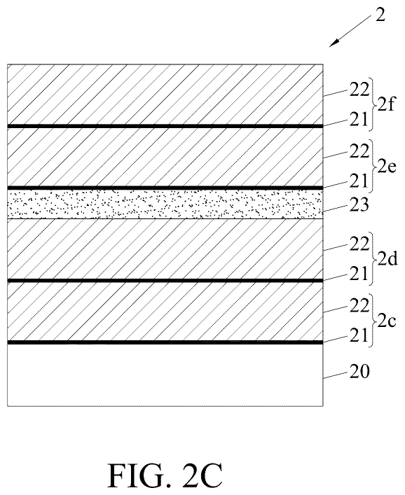

FIG. 2A is a schematic cross-sectional view of a magnetically permeable body 2 according to a first embodiment of the present disclosure. As shown in FIG. 2A, the magnetically permeable body 2 comprises: an insulating carrier layer 20 and a plurality of magnetically permeable groups 2a stacked in layers on the insulating carrier layer 20, wherein each of the magnetically permeable groups 2a includes two layers of a seed layer 21 and a magnetically permeable alloy layer 22 bonded to the seed layer 21. For example, the magnetically permeable group 2a, the seed layer 21 and the magnetically permeable alloy layer 22 below are respectively the first magnetically permeable group 2a, the first seed layer 21 and the first magnetically permeable alloy layer 22, and the magnetically permeable group 2a, the seed layer 21 and the magnetically permeable alloy layer 22 above are respectively the second magnetically permeable group 2a, the second seed layer 21 and the second magnetically permeable alloy layer 22. The first seed layer 21, the first magnetically permeable alloy layer 22, the second seed layer 21 and the second magnetically permeable alloy layer 22 are sequentially stacked above the insulating carrier layer 20, and the first magnetically permeable alloy layer 22 and the second seed layer 21 are between the first seed layer 21 and the second magnetically permeable alloy layer 22.

In one embodiment, in the method of manufacturing the magnetically permeable body 2, the insulating carrier layer 20 is first provided, and then the plurality of magnetically permeable groups 2a stacked in layers are formed on the insulating carrier layer 20.

The material of the insulating carrier layer 20 is a photosensitive or non-photosensitive insulating material and includes Ajinomoto build-up film (ABF), photosensitive resin, polyimide (PI), bismaleimide triazine (BT), flame resistant/retardant 5 (FR5) prepreg (PP), molding resin (molding compound), or epoxy molding resin (epoxy molding compound [EMC]).

The magnetically permeable alloy layer 22 is a binary or ternary alloy consisting of iron (Fe), nickel (Ni), cobalt (Co), manganese (Mn) and zinc (Zn).

The seed layer 21 is a non-pure copper seed layer, and the seed layer 21 includes materials such as nickel or an alloy thereof, a conductive polymer material, a semiconductive metal oxide (such as nickel oxide), a semiconductive inorganic oxide (such as silicon oxide), and the like, wherein the thickness of the seed layer is in micrometer or nanometer and the thickness is as thin as possible, so that the seed layer can conduct electricity but have a higher resistance value.

In one embodiment, the conductive polymer material includes one of polyaniline, polypyrrole, polythiophene, p-phenylene vinylene, or derivative thereof.

Furthermore, the method of manufacturing the magnetically permeable body 2 comprises: forming a layer of the seed layer 21 on the insulating carrier layer 20; forming a layer of the magnetically permeable alloy layer 22 on the seed layer 21 by electroplating with a patterning process; removing the seed layer 21 outside the arrangement range of the magnetically permeable alloy layer 22 by an etching process; and forming another magnetically permeable group 2a of the same structure on the magnetically permeable group 2a, so that the plurality of magnetically permeable groups 2a stacked in layers are formed on the insulating carrier layer 20. For example, the first seed layer 21 of the first magnetically permeable group 2a is formed on the insulating carrier layer 20, the first magnetically permeable alloy layer 22 of the first magnetically permeable group 2a is electroplated on the first seed layer 21 via a patterning process, and then the first seed layer 21 outside the layout range of the first magnetically permeable alloy layer 22 is removed via an etching process. Next, the second seed layer 21 of the second magnetically permeable group 2a is formed on the first magnetically permeable alloy layer 22, the second magnetically permeable alloy layer 22 of the second magnetically permeable group 2a is electroplated on the second seed layer 21 via a patterning process, and then the second seed layer 21 outside the layout range of the second magnetically permeable alloy layer 22 is removed via an etching process.

FIG. 2B is a schematic cross-sectional view of the magnetically permeable body 2 according to a second embodiment of the present disclosure. The difference between the second embodiment and the first embodiment lies in that an insulating isolation layer 23 is added between magnetically permeable groups 2b.

As shown in FIG. 2B, the insulating isolation layer 23 is formed between any two adjacent ones of the plurality of magnetically permeable groups 2b.

In one embodiment, the material of the insulating isolation layer 23 is a photosensitive or non-photosensitive insulating material and includes Ajinomoto build-up film (ABF), photosensitive resin, polyimide (PI), bismaleimide triazine (BT), FR5 prepreg (PP), molding resin (molding compound), or epoxy molding resin (epoxy molding compound).

Furthermore, the method of manufacturing the magnetically permeable body 2 comprises: forming a layer of the seed layer 21 on the insulating carrier layer 20; forming a layer of the magnetically permeable alloy layer 22 on the seed layer 21 by electroplating with a patterning process; removing the seed layer 21 outside the arrangement range of the magnetically permeable alloy layer 22 by an etching process; forming the insulating isolation layer 23 made of an insulating material on the magnetically permeable alloy layer 22; and forming another magnetically permeable group 2b of the same structure on the insulating isolation layer 23, so that the plurality of magnetically permeable groups 2b stacked in layers are formed on the insulating carrier layer 20.

FIG. 2C is a schematic cross-sectional view of the magnetically permeable body 2 according to a third embodiment of the present disclosure. The difference between the third embodiment and the foregoing embodiments lies in the number of magnetically permeable groups.

As shown in FIG. 2C, a first magnetically permeable group 2c, a second magnetically permeable group 2d, a third magnetically permeable group 2e and a fourth magnetically permeable group 2f are sequentially stacked above the insulating carrier layer 20, so that the insulating isolation layer 23 is formed between the second magnetically permeable group 2d and the third magnetically permeable group 2e, wherein the third magnetically permeable group 2e includes a third seed layer 21 and a third magnetically permeable alloy layer 22 bonded to the third seed layer 21, and the fourth magnetically permeable group 2f includes a fourth seed layer 21 and a fourth magnetically permeable alloy layer 22 bonded to the fourth seed layer 21.

In one embodiment, the method of manufacturing the magnetically permeable body 2 comprises: forming the seed layer 21 on the insulating carrier layer 20; forming the magnetically permeable alloy layer 22 on the seed layer 21 by electroplating with a patterning process; removing the seed layer 21 outside the arrangement range of the magnetically permeable alloy layer 22 by an etching process; forming the second magnetically permeable group 2d of another same structure on the first magnetically permeable group 2c; forming the insulating isolation layer 23 made of an insulating material on the second magnetically permeable group 2d; forming the third magnetically permeable group 2e of another same structure on the insulating isolation layer 23; and forming the fourth magnetically permeable group 2f of another same structure on the third magnetically permeable group 2e, so that a plurality of magnetically permeable groups stacked in layers are formed on the insulating carrier layer 20.

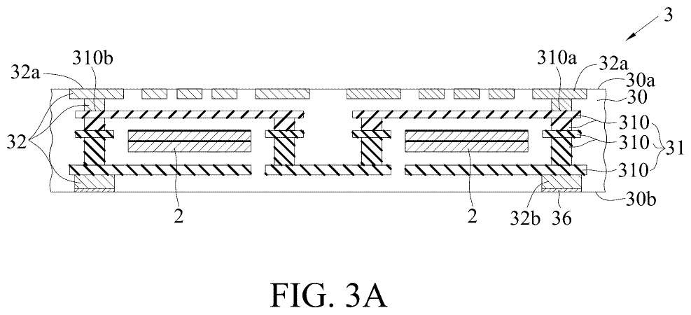

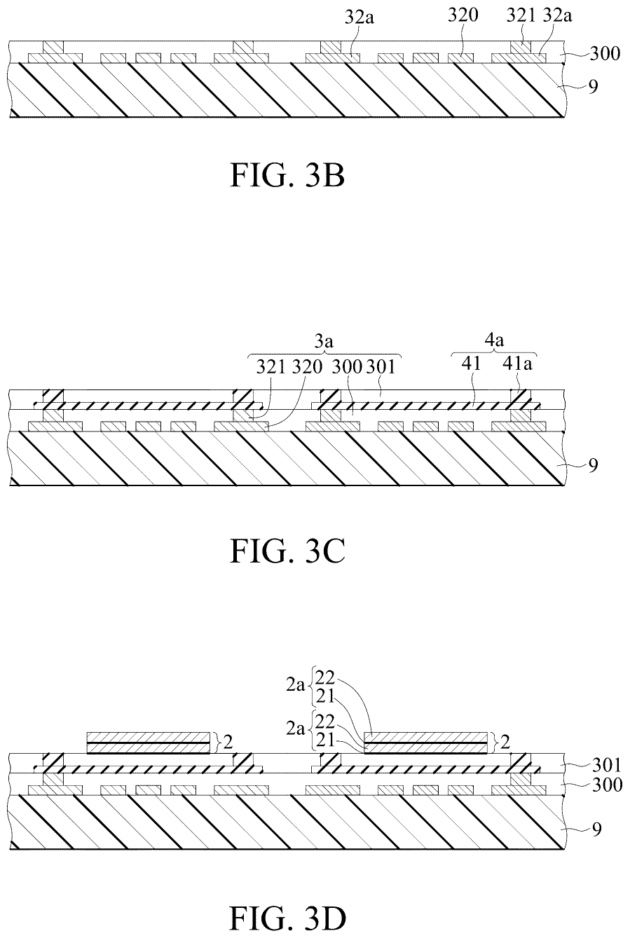

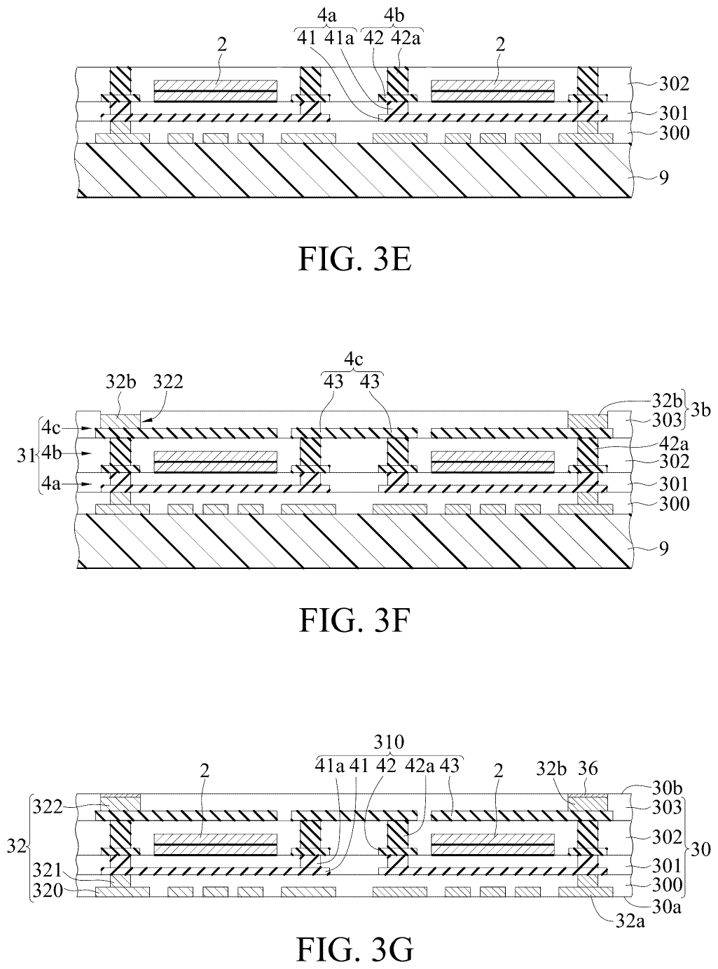

Therefore, in the magnetically permeable body 2 of the present disclosure, the magnetically permeable groups 2a, 2b (or the first magnetically permeable group 2c, the second magnetically permeable group 2d, the third magnetically permeable group 2e and the fourth magnetically permeable group 2f) are made by magnetically permeable material, so that the magnetically permeable body 2 is thickened (e.g., the magnetically permeable body 2 has a thick cross-sectional area formed by multi-layer combination or multi-layer spacing, thereby increasing the magnetic flux), and the thin seed layer 21 is used as a layer separation. Therefore, when the magnetically permeable body 2 is applied to an inductor structure 3 (as shown in FIG. 3A), the inductance value can be further increased, and the influence of eddy current and magnetic loss on the Q value (where Q stands for quality or quality factor) can be reduced.

FIG. 3A is a schematic cross-sectional view of the inductor structure 3 according to the present disclosure. As shown in FIG. 3A, the inductor structure 3 comprises: an insulator 30, at least one inductance coil 31, a conductive circuit 32 and the magnetically permeable body 2.

The insulator 30 has a first side 30a and a second side 30b opposing the first side 30a, and the material for forming the insulator 30 is a photosensitive or non-photosensitive insulating material and includes Ajinomoto build-up film (ABF), photosensitive resin, polyimide (PI), bismaleimide triazine (BT), FR5 prepreg (PP), molding resin (molding compound), or epoxy molding resin (epoxy molding compound).

The inductance coil 31 is embedded in the insulator 30 and includes a plurality of layers (such as two layers) of inductance circuits 310 that are stacked and embedded in the insulator 30 at intervals, in order to be in the shape of a toroidal coil or a helical coil.

In one embodiment, two contacts 310a, 310b of the inductance coil 31 are located on the surface of the inductance circuit 310 on one side to serve as an input port and an output port.

The conductive circuit 32 is embedded in the insulator 30 and electrically connected to the inductance coil 31, wherein the conductive circuit 32 includes a plurality of electrode pads 32a arranged on the first side 30a and partially exposed from the first side 30a, and a plurality of welding pads 32b arranged on the second side 30b and partially exposed from the second side 30b.

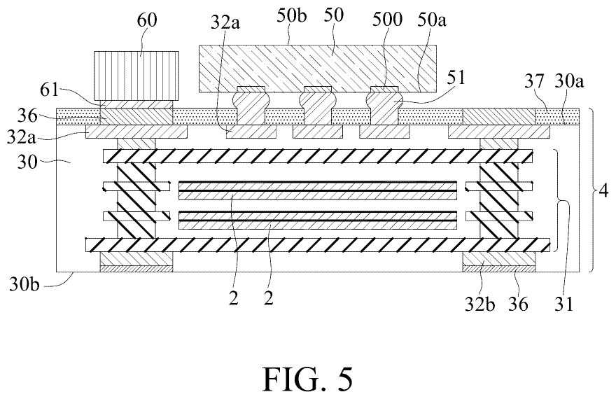

In one embodiment, the electrode pads 32a are respectively arranged on the two contacts 310a, 310b, so that the electrode pads 32a are used for externally connecting electronic elements, such as a capacitive element 60 and/or an active chip 50 shown in FIG. 5.

Moreover, a surface treatment layer 36 can be formed on the electrode pads 32a and the welding pads 32b to facilitate the placement of electronic elements, wherein the material for forming the surface treatment layer 36 is nickel/gold (Ni/Au), nickel/palladium/gold (Ni/Pd/Au), solder material, or organic solderability preservative (OSP). For example, an insulating protection layer 37 may be formed on the first side 30a (as shown in FIG. 5) or the second side 30b of the insulator 30, and the electrode pads 32a or the welding pads 32b (or the surface treatment layer 36 thereon) are exposed, wherein the material for forming the insulating protection layer 37 is a dielectric material, photosensitive or non-photosensitive organic insulating material, such as PI, ABF and EMC.

The magnetically permeable body 2 is any one of the first to third embodiments, and the magnetically permeable body 2 is embedded in the inductance coil 31 in the insulator 30, and is not electrically connected to the inductance coil 31 and the conductive circuit 32.

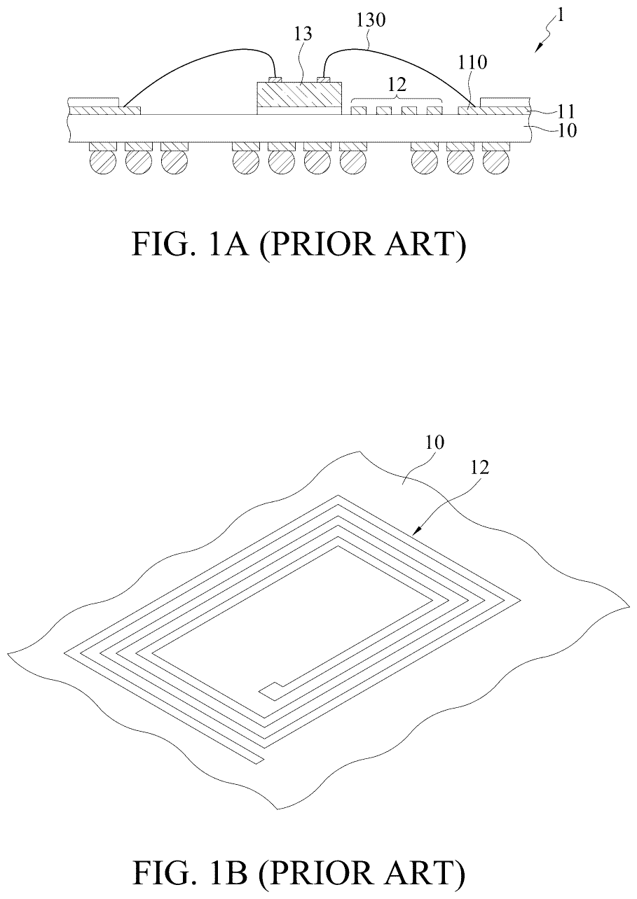

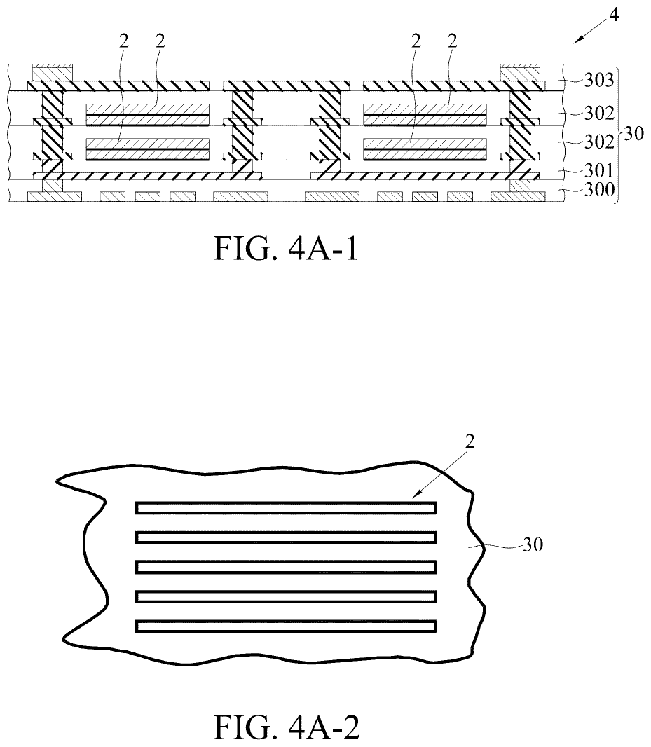

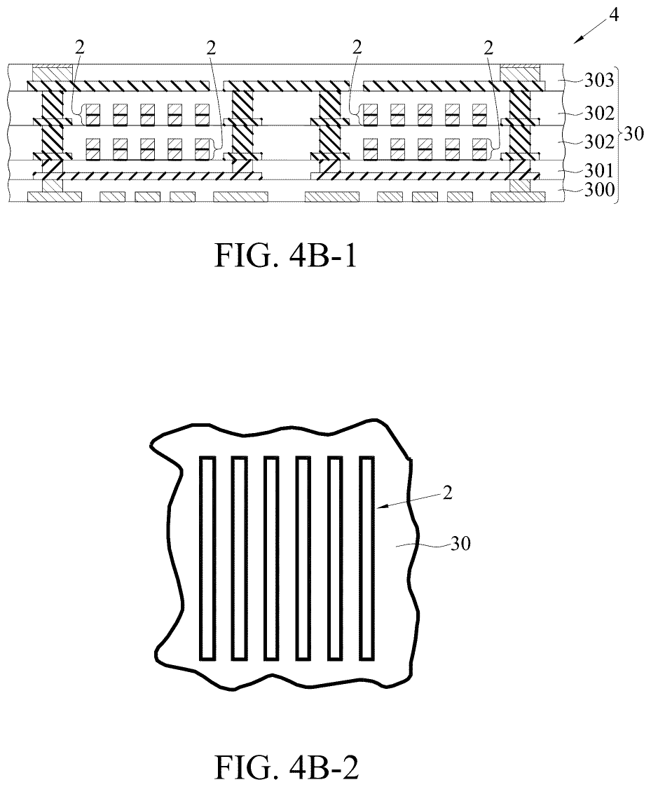

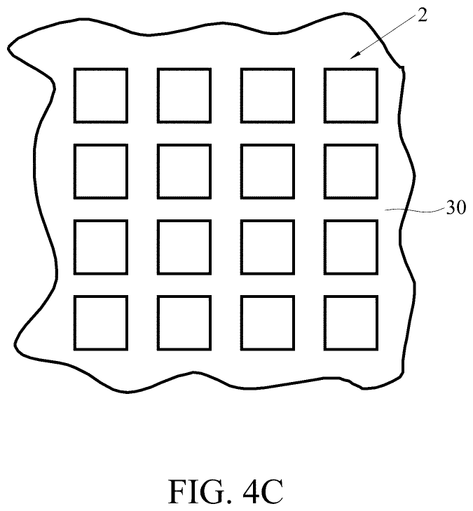

In one embodiment, a plurality of the magnetically permeable bodies 2 are arranged in the insulator 30, as shown in FIG. 4A-1. For example, the arrangement of these magnetically permeable bodies 2 is horizontally divided (as shown in FIG. 4A-2), vertically divided (as shown in FIG. 4B-1 and FIG. 4B-2), or grid-like divided (as shown in FIG. 4C).

FIG. 3B to FIG. 3G are schematic cross-sectional views illustrating a manufacturing method of the inductor structure 3 according to the present disclosure.

As shown in FIG. 3B to FIG. 3C, a carrier board 9 having a metal surface is provided, so that a first circuit structure 3a and a first inductance circuit portion 4a are formed on the metal surface of the carrier board 9 by a patterning method, wherein the first circuit structure 3a has at least one first dielectric layer 300 and the plurality of electrode pads 32a.

In one embodiment, the carrier board 9 is a detachable metal board or copper foil substrate, but the present disclosure is not limited to as such. One embodiment is illustrated by a metal board, which has separable metal materials containing copper on both sides.

Moreover, the first circuit structure 3a can be made by electroplating, sputtering, physical vapor deposition (PVD) and other methods. For example, a circuit layer 320 having the plurality of electrode pads 32a is firstly formed on the carrier board 9, then a plurality of columnar circuit layers 321 are formed on the circuit layer 320, next the first dielectric layer 300 is formed on the carrier board 9 to cover the circuit layers 320, 321, and the columnar circuit layers 321 are exposed from the first dielectric layer 300.

Also, the first inductance circuit portion 4a can also be made by means of electroplating, sputtering, or PVD, and the first inductance circuit portion 4a comprises at least one first inductance layer 41 and a plurality of columnar first inductance layers 41a, and the first inductance circuit portion 4a is embedded in another first dielectric layer 301. For example, the first inductance layer 41 made of copper is firstly formed on the first dielectric layer 300 of the first circuit structure 3a, and the first inductance layer 41 is in contact with the exposed surfaces of the columnar circuit layers 321, then the columnar first inductance layers 41a made of copper are formed on the first inductance layer 41, so that the position of each of the columnar first inductance layers 41a corresponds to the position of each of the columnar circuit layers 321. Next, another first dielectric layer 301 is formed on the first dielectric layer 300 of the first circuit structure 3a to cover the first inductance layers 41, 41a, and the columnar first inductance layers 41a are exposed from the upper first dielectric layer 301.

As shown in FIG. 3D, the process of any one of the magnetically permeable body 2 described in the first to third embodiments is performed on the upper first dielectric layer 301 to form a layered stack structure of the magnetically permeable body 2, wherein the upper first dielectric layer 301 is served as the insulating carrier layer 20.

In one embodiment, the magnetically permeable body 2 is applied with an aspect of the first embodiment shown in FIG. 2A.

As shown in FIG. 3E, a second inductance circuit portion 4b is formed on the first inductance circuit portion 4a and the first dielectric layer 301. Next, a second dielectric layer 302 is formed on the first dielectric layer 301 to cover the second inductance circuit portion 4b and the magnetically permeable body 2, and a part of the surface of the second inductance circuit portion 4b is exposed from the second dielectric layer 302.

In one embodiment, the second inductance circuit portion 4b can also be made by means of electroplating, sputtering, or PVD, wherein the second inductance circuit portion 4b includes at least one second inductance layer 42 and a plurality of columnar second inductance layers 42a, and the second inductance circuit portion 4b is embedded in the second dielectric layer 302. For example, the second inductance layer 42 made of copper is firstly formed on the first dielectric layer 301, and the second inductance layer 42 is in contact with the exposed surfaces of the columnar first inductance layers 41a, then the columnar second inductance layers 42a made of copper are formed on the second inductance layer 42, so that the position of each of the columnar second inductance layers 42a corresponds to the position of each of the columnar first inductance layers 41a. Then, the second dielectric layer 302 is formed on the first dielectric layer 301 to cover the second inductance layers 42, 42a, and the columnar second inductance layers 42a are exposed from the second dielectric layer 302.

As shown in FIG. 3F, a third inductance circuit portion 4c is formed on the second dielectric layer 302, so that the first inductance circuit portion 4a, the second inductance circuit portion 4b and the third inductance circuit portion 4c are combined into the inductance coil 31 (e.g., the first inductance circuit portion 4a, the second inductance circuit portion 4b and the third inductance circuit portion 4c are together served as the inductance coil 31). Next, a second circuit structure 3b is formed on the third inductance circuit portion 4c and the second dielectric layer 302.

In one embodiment, the third inductance circuit portion 4c can also be made by electroplating, sputtering, or PVD, and the third inductance circuit portion 4c includes at least one third inductance layer 43. For example, the third inductance layer 43 made of copper is formed on the second dielectric layer 302, and the third inductance layer 43 is in contact with the exposed surfaces of the columnar second inductance layers 42a.

Furthermore, the second circuit structure 3b has at least one third dielectric layer 303 and the plurality of welding pads 32b, wherein the plurality of welding pads 32b are exposed from the third dielectric layer 303, and the third inductance circuit portion 4c is embedded in the third dielectric layer 303.

Moreover, the second circuit structure 3b can also be made by means of electroplating, sputtering, PVD, or etching. For example, a circuit layer 322 having the plurality of welding pads 32b is firstly formed on the third inductance circuit portion 4c, so that the positions of the plurality of welding pads 32b correspond to the positions of the columnar second inductance layers 42a, then the third dielectric layer 303 is formed on the second dielectric layer 302 to cover the third inductance layer 43, the circuit layer 322 and the welding pads 32b thereof, and the third dielectric layer 303 is formed with a plurality of openings exposing the welding pads 32b.

As shown in FIG. 3G, the surface treatment layer 36 is formed on the exposed surfaces of the welding pads 32b. Next, the carrier board 9 is removed to expose the lower first dielectric layer 300, so that the plurality of electrode pads 32a are partially exposed from the lower first dielectric layer 300. Afterwards, the structure can be turned upside down to obtain the inductor structure 3 equivalent to that shown in FIG. 3A.

In one embodiment, the carrier board 9 is removed and the metal material thereof is etched, so part of the material of each of the electrode pads 32a will be slightly etched, so that the surface of each of the electrode pads 32a may be slightly recessed (or lower) than the first dielectric layer 300.

Furthermore, the first dielectric layers 300, 301, the second dielectric layer 302 and the third dielectric layer 303 are used as the insulator 30, and the circuit layers 320, 321, 322 of the first and second circuit structures 3a, 3b are used as the conductive circuit 32 for electrically connecting the inductance coil 31, wherein the insulator 30 has the first side 30a and the second side 30b opposing the first side 30a, so that the plurality of electrode pads 32a are disposed on the first side 30a and partially exposed from the first side 30a, and the plurality of welding pads 32b are disposed on the second side 30b and partially exposed from the second side 30b.

In addition, the first inductance layers 41, 41a, the second inductance layers 42, 42a and the third inductance layer 43 are the inductance circuit 310, and the inductance circuit 310 is used as the inductance coil 31, wherein the inductance coil 31 is embedded in the insulator 30, so that the magnetically permeable body 2 is embedded in the inductance coil 31 in the insulator 30 without being electrically connected to the inductance coil 31.

In addition, the magnetically permeable body 2 is manufactured by layered stacking, so that multiple groups of the magnetically permeable bodies 2 can be arranged in the insulator 30 according to requirements, such as an inductor structure 4 shown in FIG. 4A-1. For example, the arrangement of these magnetically permeable bodies 2 is horizontally divided (as shown in FIG. 4A-2), vertically divided (as shown in FIG. 4B-1 and FIG. 4B-2), or grid-like divided (as shown in FIG. 4C). It should be understood that the aspect of these magnetically permeable bodies 2 can be any one of the first to third embodiments, so the aspect of each group of the magnetically permeable bodies can be the same or different.

Therefore, in the inductor structure 3, 4 of the present disclosure, the design of the conductive circuit 32 and the change of the characteristics of the dielectric material (the insulator 30) are adopted to design the circuit as an inductance coil (such as the inductance coil 31), wherein an alloy metal material with high magnetic permeability (such as the magnetically permeable body 2) is formed in the middle of the inductance coil 31 to obtain an inductance (that is, a combination of the inductance coil 31 and the magnetically permeable body 2) with a large magnetic flux (that is to meet the requirements of larger inductance value or thinning). Therefore, the inductance and the conductive circuit 32 for transmitting signals are manufactured synchronously.

It should be understood that only the inductor structure 3, 4 can be fabricated via the build-up circuit process without fabricating the conductive circuit 32, so as to obtain flat/thin inductance elements (or electromagnetic elements), in order to achieve the purpose of miniaturization or thinning of products.

Furthermore, an alloy metal with a high magnetic permeability is used in combination with a substrate manufacturing method to produce an inductance element having the magnetically permeable body 2. Therefore, the inductor structure 3, 4 is beneficial to various designs and applications because the magnetically permeable material and the dielectric layers (such as the first dielectric layers 300, 301, the second dielectric layer 302 and the third dielectric layer 303) can be easily used for the patterning circuit process.

In the subsequent process, the capacitive element 60 and/or the active chip 50 can be electrically bonded and packaged on the plurality of electrode pads 32a, as shown in FIG. 5.

In one embodiment, the active chip 50 is a semiconductor chip, wherein the active chip 50 has an active surface 50a and an inactive surface 50b opposing the active surface 50a, and the active surface 50a has a plurality of contacts 500 for flip-chip bonding of a plurality of solder bumps 51 onto the electrode pads 32a having smaller end surfaces. Alternatively, the capacitive element 60 is a passive element, and the capacitive element 60 is bonded onto the electrode pad 32a having a larger end surface via a conductive layer 61.

To sum up, in the inductor structure 3, 4 and the magnetically permeable body 2 and the manufacturing method thereof of the present disclosure, the magnetically permeable body 2 is made of a magnetically permeable material to thicken the magnetically permeable body 2, and is manufactured by the processing method of a printed circuit board (PCB) or an integrated circuit (IC) carrier board, so as to easily carry out mass production of large board area, wherein the magnetically permeable material is formed by electroplating or deposition with a patterned build-up circuit manufacturing method without core layer (coreless), so that the precision control of the magnetically permeable body 2 is excellent. Therefore, compared with the prior art, the precision control of the inductance value of the inductor structure 3, 4 of the present disclosure is excellent. Moreover, because the inductor structure 3, 4 of the present disclosure can be embedded in the package substrate, the production process can be reduced to reduce costs, and because tiny inductance elements can be produced, the purpose of miniaturization or thinning of products can be achieved.

Furthermore, the inductance coil 31 is designed to be located in the insulator 30 by using the IC carrier board manufacturing process, so compared with the prior art, the inductor structure 3, 4 of the present disclosure can reduce the manufacturing cost.

Also, compared to the configuration of the iron core blocks of the prior art, the thickness of the inductor structure 3, 4 of the present disclosure can be adjusted according to requirements without the need to configure iron core blocks. Therefore, the present disclosure is easier to miniaturize, so that the application products such as package substrates can meet the miniaturization requirements.

In addition, the insulator 30 of the inductor structure 3, 4 of the present disclosure is easy to manufacture without doping magnetic powder. Therefore, the manufacturing cost can be reduced, and application products can meet the requirements of economic benefits.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A magnetically permeable body, comprising:
an insulating carrier layer; and
a first magnetically permeable group and a second magnetically permeable group stacked in layers on the insulating carrier layer, wherein the first magnetically permeable group includes a first seed layer and a first magnetically permeable alloy layer bonded to the first seed layer, the second magnetically permeable group includes a second seed layer and a second magnetically permeable alloy layer bonded to the second seed layer, wherein the first seed layer, the first magnetically permeable alloy layer, the second seed layer and the second magnetically permeable alloy layer are sequentially stacked above the insulating carrier layer, and the first magnetically permeable alloy layer and the second seed layer are positioned between the first seed layer and the second magnetically permeable alloy layer.

2. The magnetically permeable body of claim 1, wherein the first magnetically permeable alloy layer and/or the second magnetically permeable alloy layer contains a binary or ternary alloy consisting of iron, nickel, cobalt, manganese and zinc.

3. The magnetically permeable body of claim 1, wherein the first seed layer and/or the second seed layer is a non-pure copper seed layer, and the seed layer includes nickel or an alloy thereof, a conductive polymer material, a semiconductive metal oxide, or a semiconductive inorganic oxide.

4. The magnetically permeable body of claim 3, wherein the conductive polymer material includes one of polyaniline, polypyrrole, polythiophene, p-phenylene vinylene, and derivative thereof.

5. The magnetically permeable body of claim 1, wherein the first magnetically permeable group and the second magnetically permeable group have an insulating isolation layer formed therebetween.

6. The magnetically permeable body of claim 1, wherein the first magnetically permeable group, the second magnetically permeable group, a third magnetically permeable group and a fourth magnetically permeable group are sequentially stacked above the insulating carrier layer, and the second magnetically permeable group and the third magnetically permeable group have an insulating isolation layer formed therebetween, wherein the third magnetically permeable group includes a third seed layer and a third magnetically permeable alloy layer bonded to the third seed layer, and the fourth magnetically permeable group includes a fourth seed layer and a fourth magnetically permeable alloy layer bonded to the fourth seed layer.

7. A method of manufacturing a magnetically permeable body, comprising:
providing an insulating carrier layer;
forming a first seed layer of a first magnetically permeable group on the insulating carrier layer, electroplating a first magnetically permeable alloy layer of the first magnetically permeable group on the first seed layer via a patterning process, and removing the first seed layer outside a layout range of the first magnetically permeable alloy layer via an etching process; and
forming a second seed layer of a second magnetically permeable group on the first magnetically permeable alloy layer, electroplating a second magnetically permeable alloy layer of the second magnetically permeable group on the second seed layer via a patterning process, and removing the second seed layer outside a layout range of the second magnetically permeable alloy layer via an etching process;
wherein the first magnetically permeable group and the second magnetically permeable group are stacked in layers on the insulating carrier layer, the first magnetically permeable group includes the first seed layer and the first magnetically permeable alloy layer bonded to the first seed layer, the second magnetically permeable group includes the second seed layer and the second magnetically permeable alloy layer bonded to the second seed layer, and wherein the first seed layer, the first magnetically permeable alloy layer, the second seed layer and the second magnetically permeable alloy layer are sequentially stacked above the insulating carrier layer, and the first magnetically permeable alloy layer and the second seed layer are between the first seed layer and the second magnetically permeable alloy layer.

8. The method of claim 7, wherein the first magnetically permeable alloy layer and/or the second magnetically permeable alloy layer contains a binary or ternary alloy consisting of iron, nickel, cobalt, manganese and zinc.

9. The method of claim 7, wherein the first seed layer and/or the second seed layer is a non-pure copper seed layer, and the seed layer includes nickel or an alloy thereof, a conductive polymer material, a semiconductive metal oxide, or a semiconductive inorganic oxide.

10. The method of claim 9, wherein the conductive polymer material includes one of polyaniline, polypyrrole, polythiophene, p-phenylene vinylene, and derivative thereof.

11. The method of claim 7, wherein the first magnetically permeable group and the second magnetically permeable group have an insulating isolation layer formed therebetween.

12. The method of claim 7, wherein the first magnetically permeable group, the second magnetically permeable group, a third magnetically permeable group and a fourth magnetically permeable group are sequentially stacked above the insulating carrier layer, and the second magnetically permeable group and the third magnetically permeable group have an insulating isolation layer formed therebetween, wherein the third magnetically permeable group includes a third seed layer and a third magnetically permeable alloy layer bonded to the third seed layer, and the fourth magnetically permeable group includes a fourth seed layer and a fourth magnetically permeable alloy layer bonded to the fourth seed layer.

13. An inductor structure, comprising:
an insulator having a first side and a second side opposing the first side;
at least one inductance coil embedded in the insulator;
a conductive circuit embedded in the insulator and electrically connected to the inductance coil, wherein the conductive circuit includes a plurality of electrode pads disposed on the first side and partially exposed from the first side, and a plurality of welding pads disposed on the second side and partially exposed from the second side; and
the magnetically permeable body of claim 1 embedded in the inductance coil in the insulator, wherein the magnetically permeable body is free from being electrically connected to the inductance coil.

14. The inductor structure of claim 13, wherein the plurality of electrode pads are electrically bonded to package a capacitive element and/or an active chip.

15. The inductor structure of claim 13, wherein a material for forming the insulator is a photosensitive or non-photosensitive insulating material and includes Ajinomoto build-up film, photosensitive resin, polyimide, bismaleimide triazine, flame resistant 5 (FR5) prepreg, molding compound, or epoxy molding compound.

16. The inductor structure of claim 13, wherein the magnetically permeable body is vertically divided, horizontally divided, or grid-like divided.

17. A method of manufacturing an inductor structure, comprising:
providing a carrier board having a metal surface;
forming a first circuit structure and a first inductance circuit portion on the carrier board, wherein the first circuit structure has at least one first dielectric layer and a plurality of electrode pads;
forming the magnetically permeable body of claim 1 on the first dielectric layer, wherein the first dielectric layer is used as the insulating carrier layer;
forming a second inductance circuit portion on the first inductance circuit portion and the first dielectric layer;
forming a second dielectric layer to cover the second inductance circuit portion and the magnetically permeable body, wherein part of a surface of the second inductance circuit portion is exposed from the second dielectric layer;
forming a third inductance circuit portion on the second dielectric layer, wherein the first inductance circuit portion, the second inductance circuit portion and the third inductance circuit portion are combined into an inductance coil;
forming a second circuit structure on the third inductance circuit portion and the second dielectric layer, wherein the second circuit structure has at least one third dielectric layer and a plurality of welding pads, and the plurality of welding pads are exposed from the third dielectric layer, wherein the first dielectric layer, the second dielectric layer and the third dielectric layer are served as an insulator, and the first circuit structure and the second circuit structure form a conductive circuit that is electrically connected to the inductance coil; and
removing the carrier board to expose the plurality of electrode pads, wherein the insulator has a first side and a second side opposing the first side, wherein the plurality of electrode pads are disposed on the first side and are partially exposed from the first side, and the plurality of welding pads are disposed on the second side and are partially exposed from the second side.

18. The method of claim 17, further comprising electrically bonding to package a capacitive element and/or an active chip on the plurality of electrode pads.

19. The method of claim 17, wherein the first magnetically permeable group and the second magnetically permeable group have an insulating isolation layer formed therebetween.

20. The method of claim 17, wherein a third magnetically permeable group and a fourth magnetically permeable group are sequentially stacked above the second magnetically permeable group, and the second magnetically permeable group and the third magnetically permeable group have an insulating isolation layer formed therebetween.
